(19) United States
(12) Patent Application Publication
(10) Pub. No.: US 2013/0049541 A1
(43) Pub. Date: Feb. 28, 2013

(54) SURFACE MOUNT TYPE PIEZOELECTRIC DEVICE

(71) Applicants: YOSHIAKI AMANO, SAITAMA (JP); KENJI KAMEZAWA, SAITAMA (JP)

(72) Inventors: YOSHIAKI AMANO, SAITAMA (JP); KENJI KAMEZAWA, SAITAMA (JP)

(73) Assignee: NIHON DEMPA KOGYO CO., LTD., TOKYO (JP)

(21) Appl. No.: 13/587,935

(22) Filed: Aug. 17, 2012

(30) Foreign Application Priority Data
Aug. 23, 2011 (JP) 2011-181059

(51) Int. Cl. H01L 41/053; H01L 41/047

(52) U.S. Cl. 310/340

(57) ABSTRACT

A piezoelectric device includes a rectangular base plate having a first face where a pair of mounting terminals are formed, a second face opposite to the first face, where a bonding face is formed in a circumference, and a pair of connecting electrodes formed in the bonding face; a rectangular piezoelectric vibrating piece having a pair of excitation electrodes and lead electrodes extracted from a pair of the excitation electrodes, so that the lead electrode is fixed to the connecting electrode using a conductive adhesive; a lid plate that covers the piezoelectric vibrating piece; and a ring-shaped encapsulating material arranged in a ring shape between the bonding face and the lid plate to encapsulate the base plate and the lid plate. The connecting electrode is formed in a comb-tooth shape as seen from a normal direction of the second face to increase a lateral length of the connecting electrode.

### CROSS REFERENCE TO RELATED APPLICATIONS

This application claims the priority benefit of Japan application serial no. 2011-181059, filed on Aug. 23, 2011. The entirety of the above-mentioned patent application is hereby incorporated by reference herein and made a part of this specification.

### TECHNICAL FIELD

This disclosure relates to a surface mount type piezoelectric device, and more particularly, to a piezoelectric device having improved adhesion strength between a base plate and an electrode in an area where an encapsulating material is formed.

### DESCRIPTION OF THE RELATED ART

In a surface mount type piezoelectric device, a crystal resonating piece is stored in an insulative base plate made of glass, ceramic, and the like. The insulative base plate is encapsulated with a lid plate using an encapsulating material. For example, Patent Literature 1 discloses a method of manufacturing a piezoelectric device. The method of manufacturing the piezoelectric device includes following steps. Print an encapsulating material such as low-melting glass on a bonding face of the base plate, overlap the base plate and the lid plate, and perform heating and pressing to encapsulate the base plate and the lid plate.
[Patent Literature 1] Japanese Patent Application Laid-open No. 2004-297372

In recent years, as electronic apparatuses are miniaturized, it is necessary to further miniaturize the crystal device. Along with the miniaturization, an area of the electrode formed on the bonding face of the base plate is also reduced so that a part of the electrode may be exfoliated through cleaning after forming the electrode, and the like. In addition, when a strong external impact is applied, the encapsulating material may be exfoliated from a part of the bonding face.

A need thus exists for a piezoelectric device that the exfoliation of the electrode and the encapsulating material is reduced to improve an impact resistance.

### SUMMARY

According to a first aspect of the disclosure, there is provided a piezoelectric device including: a rectangular base plate having a first face where a pair of mounting terminals are formed, a second face opposite to the first face, where a bonding face is formed in a circumference, and a pair of connecting electrodes formed in the bonding face; a rectangular piezoelectric vibrating piece having a pair of excitation electrodes and lead electrodes extracted from a pair of the excitation electrodes, so that the lead electrode is fixed to the connecting electrode using a conductive adhesive; a lid plate that covers the piezoelectric vibrating piece; and a ring-shaped encapsulating material arranged in a ring shape between the bonding face and the lid plate to encapsulate the base plate and the lid plate. The connecting electrode is formed in a comb-tooth shape as seen from a normal direction of the second face to increase a lateral length of the connecting electrode in an area overlapped with the encapsulating material.

According to a second aspect of the disclosure, there is provided a piezoelectric device including: a rectangular base plate having a first face where a pair of mounting terminals are formed, a second face opposite to the first face, and a pair of connecting electrodes formed in an edge portion of the second face; a piezoelectric vibrating piece having a vibrating portion where a pair of excitation electrodes are formed, a frame surrounding the vibrating portion, a connecting portion connecting the vibrating portion and the frame, and lead electrodes extracted from a pair of the excitation electrodes, the lead electrodes being connected to the connecting electrodes; a lid plate bonded to the frame; and a ring-shaped encapsulating material arranged in a ring shape between the bonding face and the frame to encapsulate the base plate and the piezoelectric vibrating piece. The connecting electrode is formed in a comb-tooth shape as seen from a normal direction of the second face to increase a lateral length of the connecting electrode in an area overlapped with the encapsulating material.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view illustrating a first crystal resonator 100 according to a first embodiment of the disclosure;

FIG. 2A is a cross-sectional view taken along a line A-A′ of FIG. 1 for illustrating the first crystal resonator;

FIG. 2B is a top plan view illustrating a first base plate 40 of the first crystal resonator 100;

FIG. 3A is an enlarged view illustrating a portion EL surrounded by a circle of FIG. 2;

FIG. 3B is an exemplary cross-sectional view taken along a line B-B′ of FIG. 3A;

FIG. 3C is another exemplary cross-sectional view taken along a line B-B′ of FIG. 3A;

FIG. 4A is a top plan view illustrating a first modification of the connecting electrode 408;

FIG. 4B is a top plan view illustrating a second modification of the connecting electrode 408;

FIG. 4C is a top plan view illustrating a third modification of the connecting electrode 408;

FIG. 5 is a flow chart illustrating a process of manufacturing the first crystal resonator 100 according to the first embodiment of the disclosure;

FIG. 6 is a top plan view illustrating a base wafer 40W;

FIG. 7 is an exploded perspective view illustrating a second crystal resonator 110 according to a second embodiment of the disclosure;

FIG. 8A is a cross-sectional view taken along a line C-C′ of FIG. 7 for illustrating the second crystal resonator 110;

FIG. 8B is a top plan view illustrating a second base plate 41 of the second crystal resonator 110;

FIG. 9 is an exploded perspective view illustrating a third crystal resonator 120 according to a third embodiment of the disclosure;

FIG. 10A is a cross-sectional view taken along a line D-D′ of FIG. 9 for illustrating the third crystal resonator 120; and

FIG. 10B is a top plan view illustrating a third base plate 42 of the third crystal resonator 120.

### DETAILED DESCRIPTION

### First Embodiment

### <Entire Configuration of First Crystal Resonator 100>

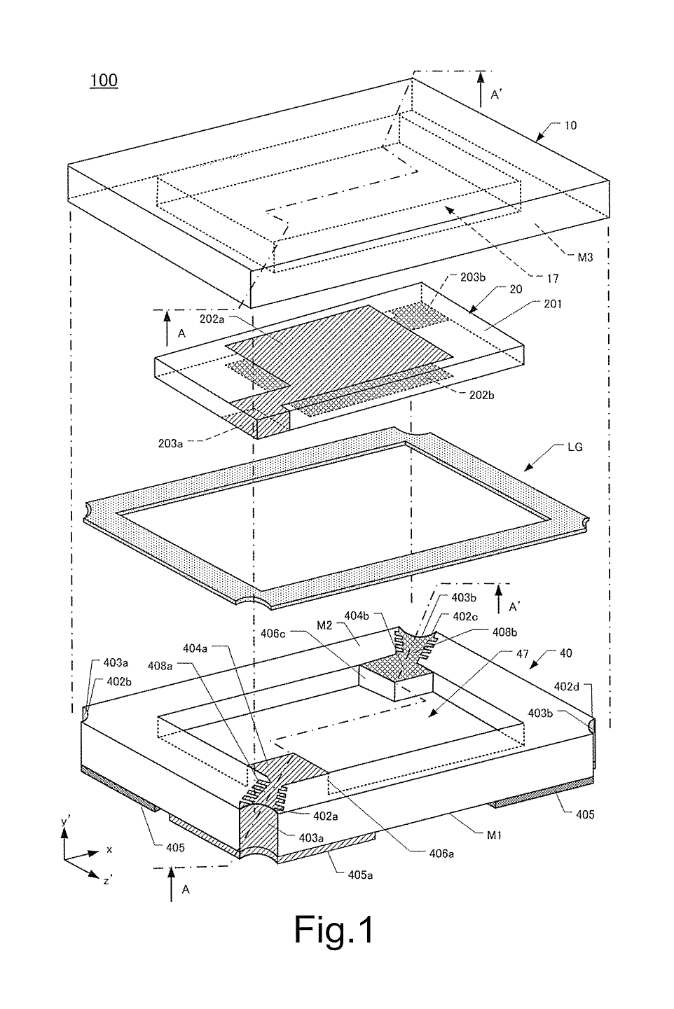

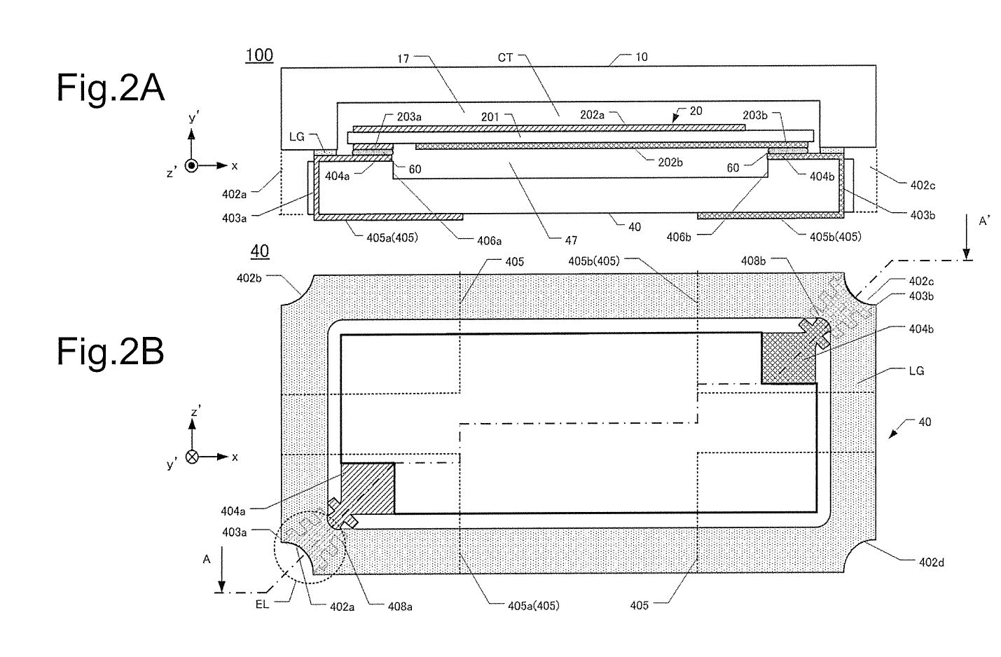

The entire configuration of the first crystal resonator 100 will be described with reference to FIGS. 1, 2A, and 2B. FIG. 1 is an exploded perspective view illustrating the first crystal resonator 100. FIG. 2A is a cross-sectional view taken along a line A-A′ of FIG. 1 for illustrating the first crystal resonator 100. FIG. 2B is a top plan view illustrating the first base plate 40 of the first crystal resonator 100. In FIG. 2B, the lid plate 10 and the first crystal resonating piece 20 are not illustrated for brevity purposes.

According to the first embodiment of the disclosure, an AT-cut first crystal resonating piece 20 is used as the crystal resonating piece. The AT-cut crystal resonating piece has a principal face (YZ plane) passing through the X-axis and inclined by 35° 15′ from the Z-axis in the Y-axis direction of the crystal axes in the XYZ coordinate system. For this reason, according to the first embodiment of the disclosure, axes y′ and z′ inclined with respect to the axis direction of the AT-cut crystal resonating piece are newly defined. Specifically, according to the first embodiment of the disclosure, the longitudinal direction of the first crystal resonator 100 is defined as x-axis direction, the height direction of the first crystal resonator 100 is defined as a y′-axis direction, a direction perpendicular to the x and y′ axes is defined as a z′-axis direction. The aforementioned definition will be similarly applied to the second and third embodiments of the disclosure.

As illustrated in FIG. 1, the first crystal resonator 100 includes a first lid plate 10 having a lid plate hollow portion 17, a first base plate 40 having a base plate hollow portion 47, and a first crystal resonating piece 20 placed on the first base plate 40.

The first crystal resonating piece 20 includes an AT-cut crystal piece 201. A pair of excitation electrodes 202a and 202b is oppositely arranged on both principal faces in the vicinity of the center of the crystal piece 201. In addition, a lead electrode 203a extending up to the −x side of the bottom face (−y′ side) of the crystal piece 201 is connected to the excitation electrode 202a. A lead electrode 203b extending up to the +x side of the bottom face (−y′ side) of the crystal piece 201 is connected to the excitation electrode 202b. Furthermore, the excitation electrodes and the lead electrodes are formed, for example, by using a chrome layer as a base layer and using a gold layer on top of the chrome layer.

The first base plate 40 is made of crystal, borate glass, or the like. The first base plate 40 includes a base plate hollow portion 47 in a side of the +y′ and a second face M2 formed around the base plate hollow portion 47. The base plate hollow portion 47 has pedestals 406a and 406c in two corners. The pedestals 406a and 406c are protruded toward the center of the base plate hollow portion 47 with the same height as that of the second face M2. Deck portions 404a and 404b for placing a pair of crystal resonating pieces are formed on the pedestals 406a and 406c, respectively.

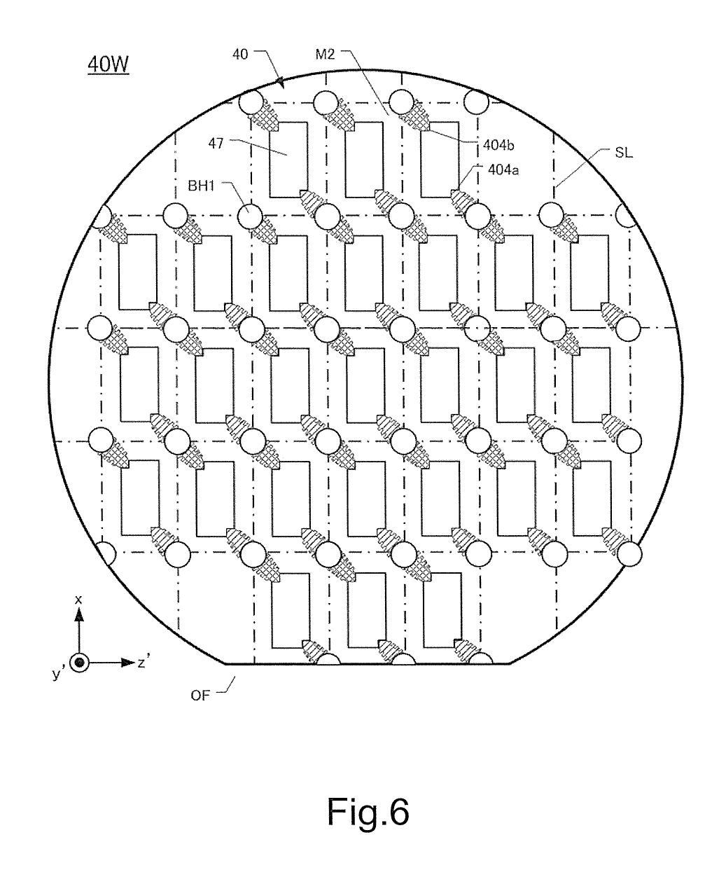

Four corners 402a, 402b, 402c, and 402d of the first base plate 40 are castellated by dicing the through-hole BH1 (refer to FIG. 6) in the first base plate 40. Lateral electrodes 403a and 403b are formed in the castellated portions 402a and 402c, respectively, of the base plate. In addition, a connecting electrode 408a electrically connected to the lateral electrode 403a is formed in the −x side of the second face M2 of the first base plate 40. Similarly, the connecting electrode 408b electrically connected to the lateral electrode 403b is formed in the +x side of the second face M2 of the first base plate 40. The connecting electrodes 408a and 408b are fanned in a comb-tooth shape such that its lateral length increases as seen from the y′-axis direction. In addition, the first base plate 40 has a pair of mounting terminals 405a and 405b electrically connected to the lateral electrodes 403a and 403b, respectively, in the mounting face M1 (refer to FIG. 2B).

The first lid plate 10 is made of crystal, borate glass, or the like. The first lid plate 10 includes a lid plate hollow portion 17 in the −y′ side and a third face M3 formed around the base plate hollow portion 47. The lid plate hollow portion 17 and the base plate hollow portion 47 provide a cavity CT for storing the first crystal resonating piece 10. The cavity CT is filled with an inert gas or hermetically sealed in vacuum.

An encapsulating material LG made of low-melting glass is arranged between the second face M2 of the first base plate 40 and the third face M3 of the first lid plate 10. The encapsulating material LG is used to bond the first base plate 40 and the first lid plate 10.

The encapsulating material LG of low-melting glass includes a lead-free vanadium-based glass melting at a temperature of 350° C. to 400° C. The vanadium-based glass has a form of a paste where a binder and a solvent are added, and is molten and then solidified so as to adhere to other elements. A melting point of the vanadium-based glass is lower than the melting point of the first lid plate 10 or the first base plate 40 made of crystal, glass, or the like. The vanadium-based glass is highly reliable in a hermetic sealability, a waterproof property, a resistance to dampness, and the like when it is bonded. The vanadium-based glass is a nonconductive adhesive and is used to prevent moisture in the air from intruding into the cavity CT or degrading a vacuum level inside the cavity CT. The encapsulating material LG of low-melting glass has a width of, approximately, 300 μm and is printed on the outer side of the second face M2 of the first base plate 40 as illustrated in FIGS. 1, 2A, and 2B.

As illustrated in FIG. 2A, the length of the first crystal resonating piece 20 in the x-axis direction is shorter than the length of the base plate hollow portion 47 in the x-axis direction. If the first crystal resonating piece 20 is placed on the pedestals 406a and 406c of the first base plate 40 using the conductive adhesive 60, the lead electrodes 203a and 203b of the first crystal resonating piece 20 are electrically connected to the deck portions 404a and 404b, respectively, of the first base plate 40. As a result, the mounting terminals 405a and 405b are electrically connected to the excitation electrodes 202a and 202b, respectively, through the lateral electrodes 403a and 403b, the connecting electrodes 408a and 408b, the deck portions 404a and 404b, the conductive adhesive 60, and the lead electrodes 203a and 203b. That is, when an alternating voltage (alternating between positive and negative potentials) is applied to the mounting terminals 405a and 405b, the first crystal resonating piece 20 is vibrated in a thickness-shear mode.

In addition, as illustrated in FIG. 2B, the connecting electrodes 408a and 408b are foamed in a comb-tooth shape such that its lateral length increases as seen from the y′-axis direction. In addition, four mounting terminals 405 indicated by dotted lines are formed in four corners of the mounting face M1 of the first base plate 40. The mounting terminals 405a and 405b are electrically connected to the lateral electrodes 403a and 403b, respectively, and the remaining two mounting terminals 405 are used for grounding.

### <Configuration of Connecting Electrode>

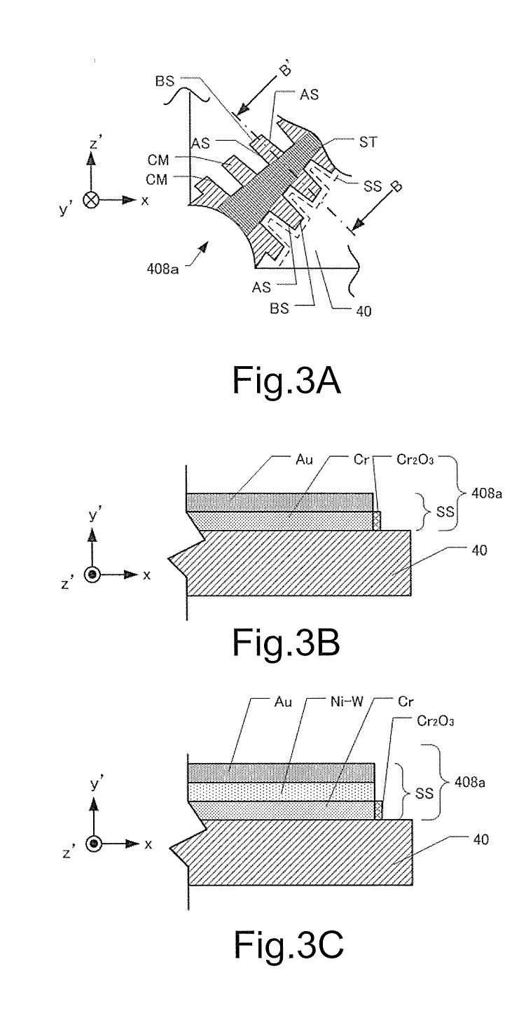

FIG. 3A is an enlarged view illustrating a portion EL surrounded by the circle of FIG. 2B. FIG. 3B is an exemplary cross-sectional view taken along a line B-B′ of FIG. 3A. FIG. 3C is another exemplary cross-sectional view taken along a line B-B′ of FIG. 3A.

While a part of the connecting electrode 408a is illustrated in FIG. 3A, the virtual area ST of the connecting electrode is illustrated to overlap for brevity purposes. The virtual area ST indicates an area from the lateral electrodes 403a and 403b to the deck portions 404a and 404b if the comb-tooth shape is not formed. The side face of the virtual area ST is straight-lined.

A difference between the connecting electrode 408a and the virtual area ST corresponds to a comb portion CM. A single comb portion CM includes two electrode side faces AS and a single electrode side face BS. Since a plurality of comb portions CM are formed, the connecting electrode 408a has a lateral length SS in one side. If a single comb portion CM is provided, the lateral length SS of the connecting electrode 408a increases by two electrode side faces AS compared to the lateral length of the virtual area S.

As illustrated in FIG. 3B, the connecting electrode 408a has a two-layered structure. A chrome layer (Cr) as a base metal film is formed on top of the first base plate 40 made of crystal, borate glass, or the like. A gold layer (Au) is formed on top of the chrome layer. The shape of the connecting electrode 408a is formed through photolithography and etching. After the etching, the side face of the chrome layer (Cr) is exposed to the air. For this reason, a chromium oxide film (Cr₂O₃) is formed on the side face of the chrome layer which is susceptible to oxidation. The chromium oxide film (Cr₂O₃) increases a bonding force with the first base plate 40 made of crystal, borate glass, or the like. Therefore, the connecting electrodes 408a and 408b are formed in a comb-tooth shape, and the lateral length SS increases. In addition, as illustrated in FIG. 2B, the encapsulating material LG of low-melting glass is printed on the connecting electrodes 408a and 408b. Since the connecting electrodes 408a and 408b are formed in a comb-tooth shape, the bonding area of the encapsulating material LG of low-melting glass increases, so that it is possible to robustly bond the first lid plate 10 and the first base plate 40.

FIG. 3C is another example of the connecting electrode 408a. The connecting electrode 408a has a three-layered structure. A nickel-tungsten alloy layer (Ni+W) is formed between a gold layer (Au) and a chrome layer (Cr) as a base metal film. The connecting electrode 408a is formed through photolithography and etching, and then, the side face of the chrome layer (Cr) is exposed to the air. For this reason, a chromium oxide film (Cr₂O₃) is formed in the side face of the chrome layer which is susceptible to oxidation. The connecting electrodes 408a and 408b having a comb-tooth shape increases the bonding force to the first base plate 40 and the bonding force of the encapsulating material LG of low-melting glass.

### <Modification of Connecting Electrode>

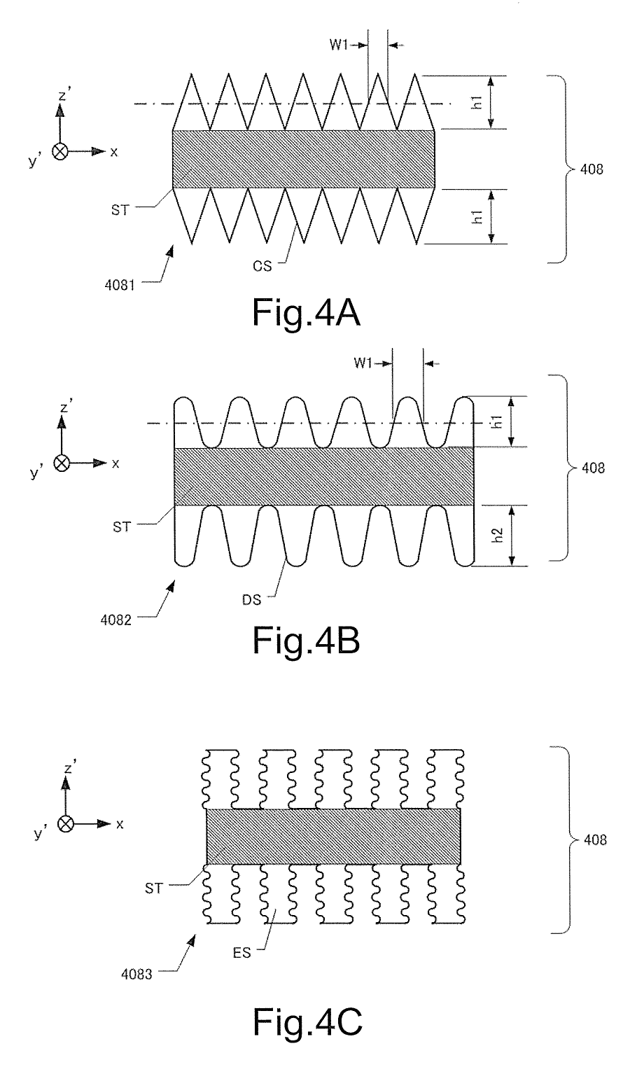

FIG. 4A is a top plan view illustrating a first modification of the connecting electrode 408. FIG. 4B is a top plan view illustrating a second modification of the connecting electrode 408. FIG. 4C is a top plan view illustrating a third modification of the connecting electrode 408. In addition, the virtual area ST straightly extending from the lateral electrode 403 to the deck portion 404 is illustrated overlappingly.

In FIG. 4A, the connecting electrode 408 is formed in a saw-tooth shape 4081. The tooth portion CS has a triangular shape. For this reason, the lateral length of the triangle increases. The tooth portion CS of FIG. 4A has the same height h1 in both side faces of the triangular shape.

In FIG. 4B, the connecting electrode 408 is formed in a wave shape 4082. The wave portion DS has a sinusoidal wave shape. For this reason, the lateral length of the sinusoidal wave shape increases. In addition, the wave portion DS illustrated in FIG. 4B has a height h1 in one side and a height h2 higher than the height h1 in the other side. In this manner, the connecting electrode 408 does not necessarily have the same height in both sides.

In FIG. 4C, the connecting electrode 408 has a corrugating shape 4083. The corrugation ES has a plurality of irregularities. Due to a plurality of irregularities, the lateral length increases. In particular, although not illustrated in the drawings, the irregularities may have a triangular shape.

Although the comb-tooth shape is formed in both sides of the connecting electrode 408 as seen from the y′ direction in FIGS. 3A to 3C and 4A to 4C, the comb portion CM may be formed in only one side. It is conceivable that various shapes other than those illustrated in FIGS. 4A to 4C may be formed. Herein, it is defined that the connecting electrode 408 has a comb-tooth shape if the lateral length of the connecting electrode 408 is twice or more than the lateral length (of the virtual area ST) straightly extending from the lateral electrode 403 to the deck portion 404. In addition, herein, the comb-tooth shape includes a saw-tooth shape, a sinusoidal wave shape, and a corrugating shape.

### <Method of Manufacturing First Crystal Resonator 100>

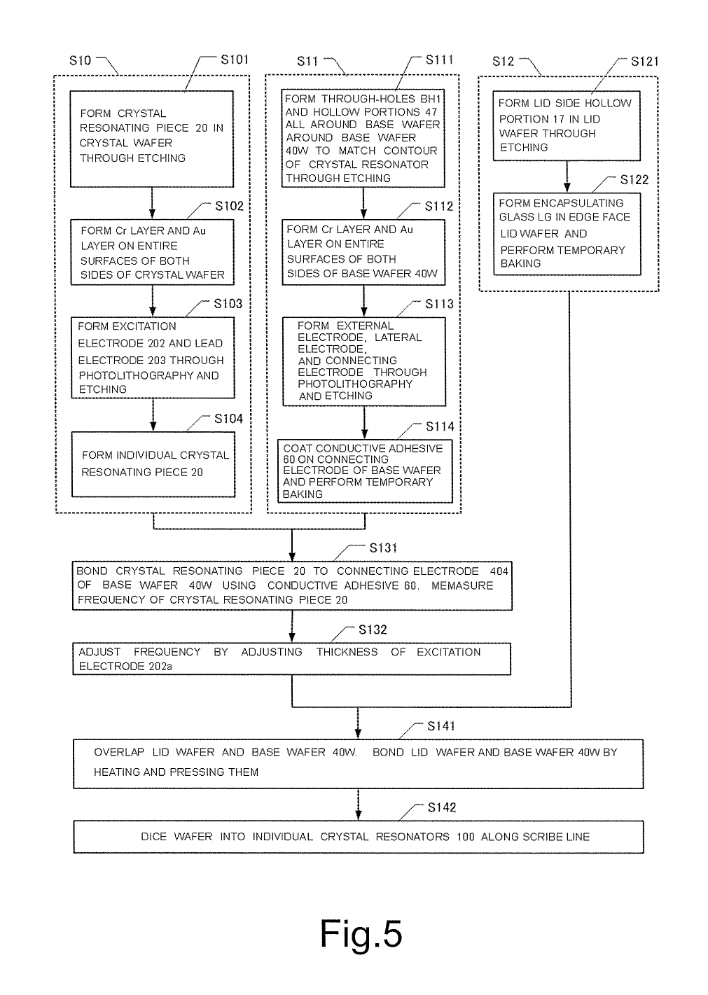

FIG. 5 is a flowchart illustrating a method of manufacturing the first crystal resonator 100. FIG. 6 is a top plan view illustrating a base wafer 40W including a plurality of base plates 40 illustrated in FIGS. 1, 2A, and 2B.

In step S10, the first crystal resonating piece 20 is manufactured. Step S10 includes steps S101 to S104. In step S101, contours of a plurality of first crystal resonating pieces 20 are formed in the crystal wafer (not illustrated) through etching. That is, a plurality of crystal pieces 201 is formed in the crystal wafer.

In step S102, the chrome layer and the gold layer are sequentially formed on both faces of the crystal wafer through sputtering or vacuum deposition. Here, the chrome layer as a base has a thickness of, for example, 0.05 to 0.1 μm. The gold layer has a thickness of, for example, 0.2 to 2 μm.

In step S103, a photoresist is uniformly coated on the entire surface of the metal layer. In addition, exposure is performed using an exposure apparatus (not illustrated) such that patterns of the excitation electrodes 202a and 202b and the lead electrodes 203a and 203b drawn on the photomask are transferred onto the crystal pattern. Then, the metal layer exposed from the photoresist is etched. As a result, the excitation electrodes 202a and 202b and the lead electrodes 203a and 203b are formed on both sides of the crystal wafer as illustrated in FIGS. 1, 2A, and 2B.

In step S104, the crystal wafer is diced so as to provide individual first crystal resonating pieces 20.

In step S11, the first base plate 40 is manufactured. Step S11 includes steps S111 to S114. In step S111, the crystal wafer 40W is prepared. In addition, the through-holes BH1 are formed all around the base wafer 40W through etching to penetrate the base wafer 40W (refer to FIG. 6). If a single through-hole BH1 is divided by four, four castellated portions 402a, 402b, 402c, and 402d are formed (refer to FIG. 2B).

In step S112, the chrome layer and the gold layer are sequentially formed in the though-hole BH1 and the mounting face M1 of the base wafer 40W through sputtering or vacuum deposition. Here, the chrome layer as a base has a thickness of, for example, 0.05 to 0.15 μm, and the gold layer has a thickness of, for example, 0.2 to 2 μm.

In step S113, the photoresist is uniformly coated on the metal layer. In addition, exposure is performed using an exposure apparatus (not illustrated) such that patterns of the mounting terminals 405, 405a, and 405b, the lateral electrodes 403a and 403b, the deck portions 404a and 404b, and the connecting electrodes 408a and 408b drawn on the photomask are transferred onto the base wafer 40W. Then, the metal layer exposed from the photoresist is etched. As a result, as illustrated in FIG. 1, 2A, and 2B, the mounting terminals 405, 405a, and 405b are formed in the mounting face M1 of the base wafer 40W, the lateral electrodes 403a and 403b are formed in the through-hole BH1, and the connecting electrodes 408a and 408b and the deck portions 404a and 404b are formed in the second face M2.

After the etching, the side face of the chrome layer of the connecting electrodes 408a and 408b is exposed to the air. In addition, a chromium oxide film is formed on the chrome exposed to the air (refer to FIGS. 3B and 3C). The chromium oxide film (Cr₂O₃) has an excellent bonding force to glass or crystal and is not easily exfoliated from the base wafer 40W.

In step S114, a conductive adhesive 60 is coated on the deck portions 404a and 404b of the base wafer 40W, and temporary baking is performed. Through the temporary baking, the gas generated from the conductive adhesive 66 is removed.

In step S12, the first lid plate 10 is manufactured. Step S12 includes steps S121 to S122. In step S121, a lid wafer is prepared. In addition, a lid plate hollow portion 17 is formed on the lid wafer through etching.

In step S122, the encapsulating material LG is uniformly formed in the third face M3 of the lid wafer (refer to FIG. 1). For example, the encapsulating material LG which is made of low-melting glass is formed in the third face M3 of the lid wafer corresponding to the second face M2 of the first base plate 40 through screen printing, and temporary baking is performed. In addition, instead of printing the encapsulating material LG on the lid wafer, the encapsulating material LG may be screen-printed on the base wafer 40W where the connecting electrode 408 has been formed.

In FIG. 5, step S10 for manufacturing the first crystal resonating piece 20, step S11 for manufacturing the first base plate 40, and step S12 for manufacturing the first lid plate 10 may be performed separately in parallel.

In step S131, the first crystal resonating piece 20 manufactured in step S10 is placed on the conductive adhesive 60 of the deck portions 404a and 404b of the first base plate 40 (refer to FIG. 1). In this case, the first crystal resonating piece 20 is placed such that positions match between the lead electrodes 203a and 203b of the first crystal resonating piece 20 and the deck portions 404a and 404b formed in the second face M2 of the first base plate 40. The conductive adhesive 60 is heated to a predetermined temperature, and the first crystal resonating piece 20 is pressed, so that the first crystal resonating piece 20 is fixed to the first base plate 40. In addition, a vibration frequency is measured for each of the first crystal resonating pieces 20.

In step S132, the thickness of the excitation electrode 202a of the first crystal resonating piece 20 is adjusted. Metal is sputtered on the excitation electrode 202a to increase the mass and lower the frequency, or reverse sputtering is performed by sublimating metal from the excitation electrode 202a to decrease the mass and increase the frequency. If the measurement result of the vibration frequency is within a predetermined range, it is not necessary to adjust the vibration frequency.

In step S141, the lid wafer and the base wafer 40W are accurately overlapped with each other with respect to the orientation flat OF. The overlapped wafers are arranged inside an inert gas chamber (not illustrated) or a vacuum chamber (not illustrated). In addition, the encapsulating material LG is heated to 350° C. to 400° C., and the lid wafer and the base wafers 40W are pressed. As a result, the lid wafer and the base wafer 40W are bonded to each other using the encapsulating material LG of low-melting glass. The cavity CT of the overlapped wafers is also filled with an inert gas or has a vacuum state. The connecting electrodes 408a and 408b having a comb-tooth shape enhances a bonding force between the lid wafer and the base wafer 40W using the encapsulating material LG of low-melting glass.

In step S142, the bonded lid wafer and base wafer 40W are diced into individual first crystal resonators 100. In the dicing process, the bonded lid wafer and base wafer 40W are diced into individual first crystal resonators 100 along the scribe line SL indicated by the one-dotted chain line in FIG. 6 using a laser dicing apparatus, a cutting-blade dicing apparatus, and the like. As a result, several hundreds to thousands of the first crystal resonators 100 are manufactured.

### Second Embodiment

### <Entire Configuration of Second Crystal Resonator 110>

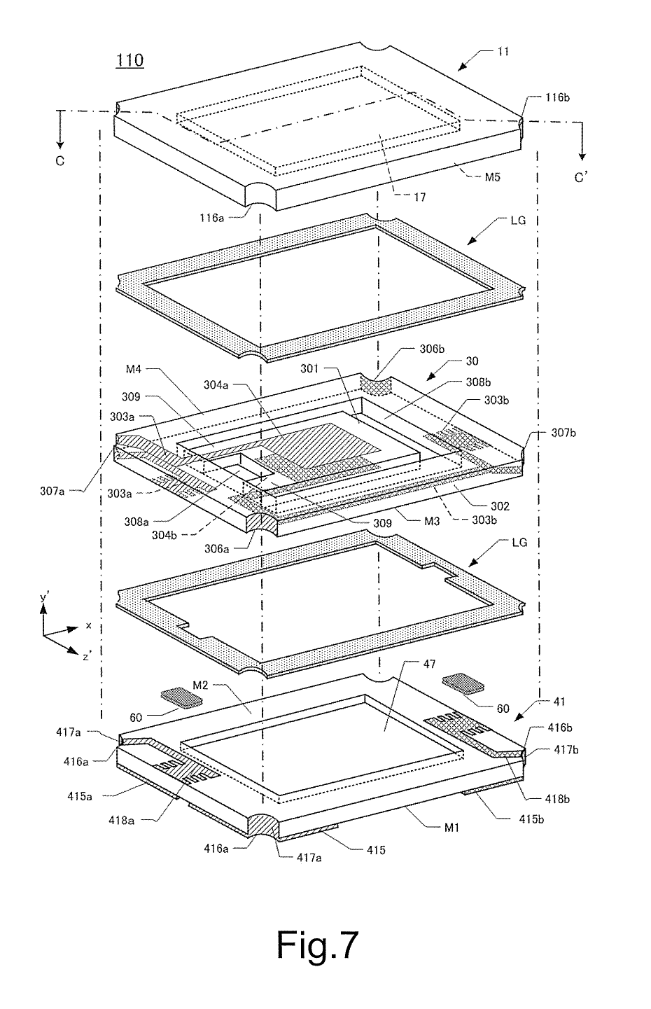

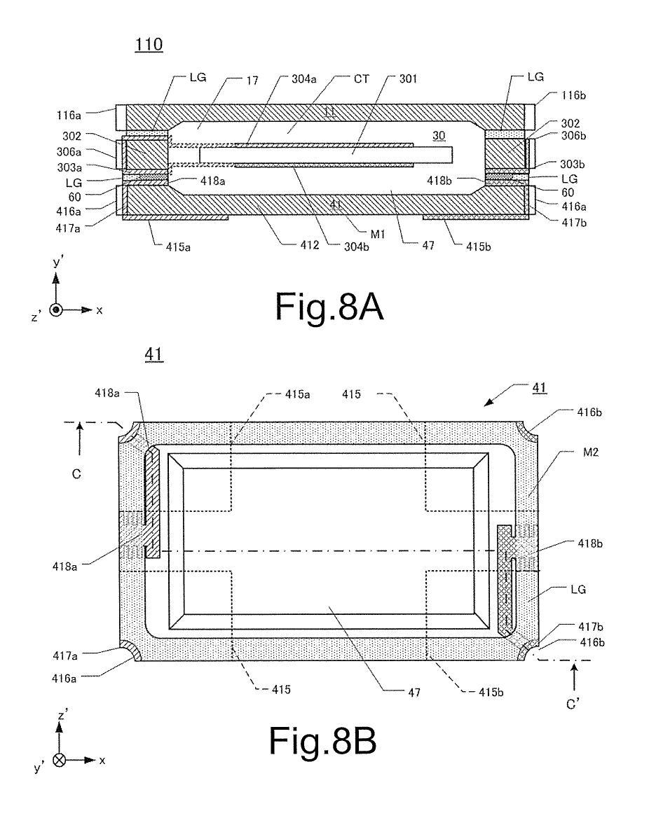

The entire configuration of the second crystal resonator 110 will be described with reference to FIGS. 7, 8A, and 8B. FIG. 7 is a perspective view illustrating the second crystal resonator 110 having a divided state as seen from the second lid plate 11 side. FIG. 8A is a cross-sectional view taken along a line C-C′ of FIG. 7 after the crystal frame 30, the second base plate 41, and the second lid plate 11 are bonded. FIG. 8B is a top plan view illustrating the second base plate 41. In addition, the conductive adhesive 60, the second lid plate 11, and the crystal frame 30 are not illustrated in FIG. 8B for brevity purposes.

The second crystal resonator 110 is different from the first crystal resonator 100 in that the second crystal resonator 110 includes the crystal frame 30 instead of the crystal resonating piece 20. In addition, the lead electrode 303 of the crystal frame 30 is formed in a comb-tooth shape. In the following description, like reference numerals denote like elements as in the first embodiment, and description thereof will not be repeated. Instead, description will be made only for the difference.

As illustrated in FIG. 7, the second crystal resonator 110 includes a second lid plate 11 having the lid plate hollow portion 17, a second base plate 41 having the base plate hollow portion 47, and an AT-cut crystal frame 30. The second base plate 41 and the second lid plate 11 are also made of a crystal material.

The crystal frame 30 includes an AT-cut rectangular crystal piece 301 and an outer frame 302 surrounding the crystal piece 301. In addition, gap portions 308a and 308b, that are vertically penetrates, are formed between the crystal piece 301 and the outer frame 302. A part where the gap portions 308a and 308b are not formed serves as a connecting portion 309 between the crystal piece 301 and the outer frame 302.

The crystal frame 30 includes a pair of excitation electrodes 304a and 304b in both principal faces in the vicinity of the center of the crystal piece 301. In addition, a lead electrode 303a extending up to one end of the −x side of the bottom face (−y′ side) of the crystal piece 301 is formed in the excitation electrode 304a, and a lead electrode 303b extending up to the other end of the +x side of the bottom face (−y′ side) of the crystal piece 301 is formed in the excitation electrode 304b. The edge portions of the lead electrodes 303a and 303b are formed in a comb-tooth shape in order to increase the lateral length of the lead electrode. The edge portions of the lead electrodes 303a and 303b are overlapped with the encapsulating material LG. The crystal frame 30 is electrically bonded to the connecting electrodes 418a and 418b through the lead electrodes 303a and 303b and the conductive adhesive 60 when it is bonded to the base plate 11 using the encapsulating material LG. The lead electrodes 303a and 303b are formed in a comb-tooth shape to increase the lateral length of the lead electrode. In addition, the encapsulating material LG formed between the crystal frame 30 and the base plate 11 is partially notched to match the area of the conductive adhesive 60.

As illustrated in FIG. 7, the second base plate 41 has the connecting electrodes 418a and 418b in the second face M2. The connecting electrode 418a is electrically connected to the mounting terminal 415a and the lateral electrode 417a. The connecting electrode 418b is electrically connected to the mounting terminal 415b and the lateral electrode 417b. In addition, the conductive adhesive 60 is formed in the connecting electrodes 418a and 418b. The connecting electrodes 418a and 418b are formed in a comb-tooth shape to increase the lateral length of the connecting electrode.

The second base plate 41 and the crystal frame 30 are heated to a temperature of 300° C. to 400° C. under a nitrogen gas atmosphere or in vacuum, and then, they are pressed. In addition, as illustrated in FIGS. 7 and 8A, the second lid plate 11, the crystal frame 30, and the second base plate 41 are bonded to each other using the encapsulating material LG. In this case, the connecting electrodes 418a and 418b and the lead electrodes 303a and 303b of the crystal frame 30 are electrically connected using the conductive adhesive 60.

The crystal castellated portions 306a and 306b are formed in four corners of the crystal frame 30. In addition, the crystal lateral electrode 307a is formed in the crystal castellated portion 306a, and the crystal lateral electrode 307a is connected to the lead electrode 303a. Similarly, the crystal lateral electrode 307b is formed in the crystal castellated portion 306b, and the crystal lateral electrode 307b is connected to the lead electrode 303b. The crystal castellated portions 306a and 306b are formed by dicing the through-hole BH1 (not illustrated).

The second base plate 41 includes a mounting face M1 and a second face M2. In addition, a pair of mounting terminals 415a and 415b are formed in the mounting face M1 of the second base plate 41, and the lateral castellated portions 416a and 416b are formed in four corners of the second base plate 41. Furthermore, the lateral electrode 417a connected to the mounting terminal 415a is formed in the lateral castellated portion 416a, and the lateral electrode 417b connected to the mounting terminal 415b is formed in the lateral castellated portion 416b. Moreover, the connecting electrode 418a connected to the lateral electrode 417a is formed in the second face M2, and the connecting electrode 418b is formed in the lateral electrode 417b.

The second lid plate 11 has a bonding face M5. The lateral castellated portions 116a and 116b are formed in four corners of the second lid plate 11. The lateral castellated portions 116a and 116b are formed by dicing the through-hole BH1 (not illustrated).

### Third Embodiment

### <Entire Configuration of Third Crystal Resonator 120>

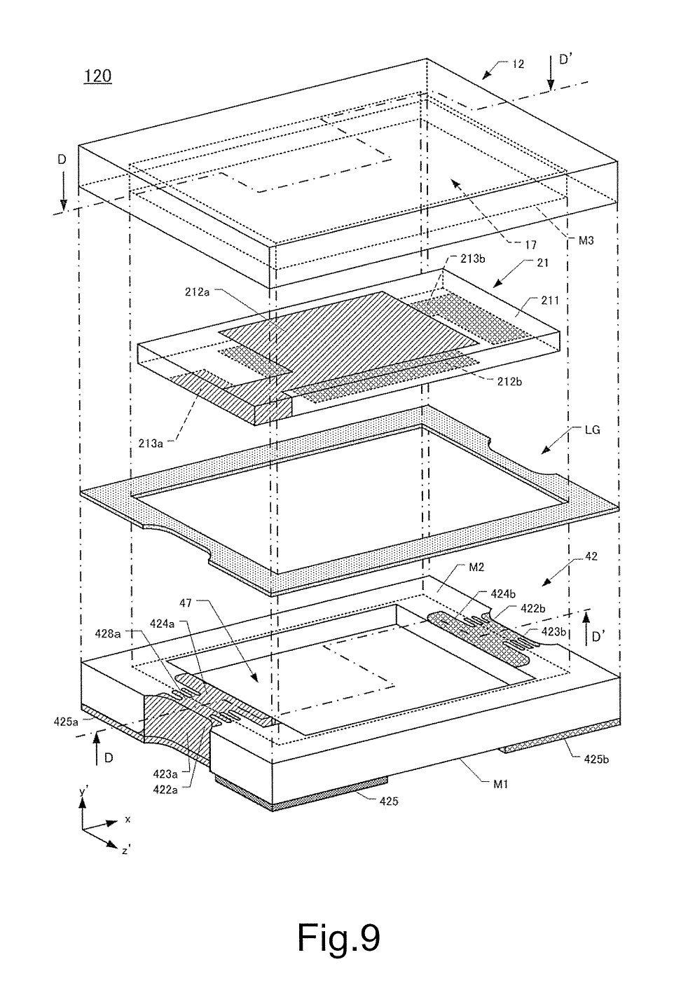

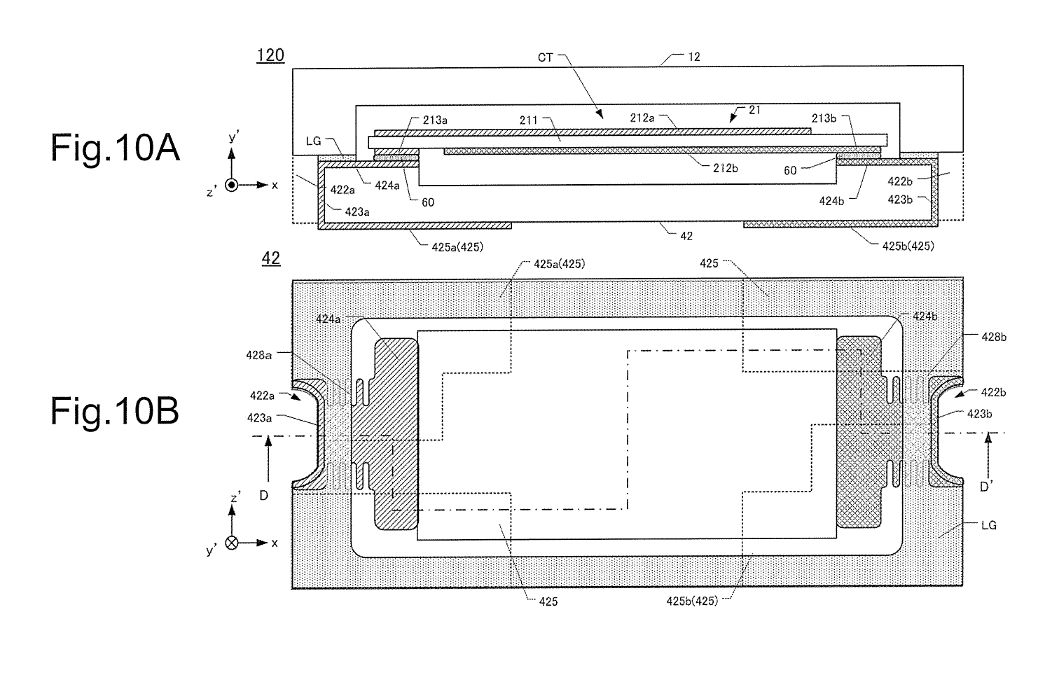

The entire configuration of the third crystal resonator 120 will be described with reference to FIGS. 9, 10A, and 10B. FIG. 9 is an exploded perspective view illustrating the third crystal resonator 120. FIG. 10A is a cross-sectional view taken along a line D-D′ of FIG. 9 for illustrating the third crystal resonator 120, and FIG. 10B is a top plan view illustrating the third base plate 42 of the third crystal resonator 120. The third crystal resonator 120 is different from the first crystal resonator 100 in that the third crystal resonator 120 includes a second crystal resonating piece 21 in a third base plate 42 instead of the first crystal resonating piece 20. In addition, the position of the castellated portion is different. In the following description, like reference numerals denote like elements as in the first embodiment, and description thereof will not be repeated. Description will be made only for the difference.

As illustrated in FIG. 9, the third crystal resonator 120 includes a third lid plate 12 having the lid plate hollow portion 17, a third base plate 42 having the base plate hollow portion 47, and a second crystal resonating piece 21 placed on the third base plate 42.

In the second crystal resonating piece 21, a pair of excitation electrodes 212a and 212b are oppositely arranged on both principal faces in the vicinity of the center of the crystal piece 211 thereof. In addition, the lead electrode 213a extending up to the −x side of the bottom face (−y′ side) of the crystal piece 211 is connected to the excitation electrode 212a, and the lead electrode 213b extending up to the +x side of the bottom face (−y′ side) of the crystal piece 211 is connected to the excitation electrode 212b. The lead electrodes 213a and 213b are formed widely in the z-axis direction.

The third base plate 42 has a second face M2 formed around the base plate hollow portion 47 on the surface (+y′ side face). In addition, in the third base plate 42, the base plate castellated portions 422a and 422b extending in the z′-axis direction are formed in both sides of the x-axis direction. The lateral electrodes 423a and 423b are formed in the base plate castellated portions 422a and 422b, respectively (refer to FIG. 10B). In addition, the connecting electrode 424a electrically connected to the lateral electrode 423a is formed in the −x side of the second face M2 of the third base plate 42. Similarly, the connecting electrode 424b electrically connected to the lateral electrode 423b is formed in the +x side of the second face M2 of the third base plate 42. Furthermore, the third base plate 42 includes a pair of mounting terminals 425, 425a, and 425b electrically connected to the lateral electrodes 423a and 423b, respectively, on the mounting face M1 (refer to FIG. 10B). The connecting electrodes 424a and 424b are formed in a wave shape 4082 as illustrated in FIG. 4B.

As illustrated in FIG. 10A, the length of the base plate hollow portion 47 in the x-axis direction is shorter than the length of the second crystal resonating piece 21 in the x-axis direction. That is, in the third crystal resonator 120, the length of the second crystal resonating piece 21 is longer than that of the base plate hollow portion 47. For this reason, if the second crystal resonating piece 21 is placed on the third base plate 42 using the conductive adhesive 60, both ends of the second crystal resonating piece 21 in the x-axis direction are placed on the second face M2 of the third base plate 42. In this case, as illustrated in FIG. 10A, the lead electrodes 213a and 213b of the second crystal resonating piece 21 are electrically connected to the connecting electrodes 424a and 424b, respectively, of the third base plate 42. As a result, the mounting terminals 425a and 425b are electrically connected to the excitation electrodes 212a and 212b, respectively, through the lateral electrodes 423a and 423b, the connecting electrodes 424a and 424b, the conductive adhesive 60, and the lead electrodes 213a and 213b. That is, when an alternating voltage (alternating between positive and negative potentials) is applied to the mounting terminals 425a and 425b, the second crystal resonating piece 21 is vibrated in a thickness-shear mode.

Since the lateral lengths of the connecting electrodes 424a and 424b increase, affinity between the connecting electrodes 424a and 424b and the third base plate 42 is improved. In addition, the third base plate 42 and the third lid plate 12 are robustly bonded using the encapsulating material.

In the piezoelectric device described above, the lead electrode may be formed in a comb-tooth shape as seen from a normal direction of the second face to increase a lateral length of the lead electrode in an area overlapped with the encapsulating material. In the piezoelectric device described above, the base plate may include a glass material or a piezoelectric material, the connecting electrode may include a chrome layer directly formed on the glass material or the piezoelectric material and a surface layer formed on the chrome layer, and a side face of the chrome layer may be oxidized. In the piezoelectric device described above, a nickel-tungsten alloy layer may be included between the chrome layer and the surface layer.

In the piezoelectric device disclosed herein, adhesion between the connecting electrode and the base plate is improved by increasing the area of the side face of the connecting electrode in order to prevent exfoliation of the electrode. In addition, encapsulation between the lid plate and the base plate is also improved by increasing the area of the side face of the connecting electrode.

While best modes or embodiments of the invention have been described in detail hereinbefore, those skilled in the art will be appreciated that variations and changes may be made without departing from the scope or spirit of the present invention.

Although the lid plate and the base plate are bonded using low-melting glass LG which is a nonconductive adhesive in the first to third embodiments of the disclosure, polyimide resin may be used instead of the low-melting glass LG. The crystal resonating piece according to the first to third embodiments of the disclosure may be basically applied to a piezoelectric material including lithium tantalate, lithium niobate, or piezoelectric ceramic as well as the crystal material. Furthermore, the crystal resonating piece according to the first to third embodiments of the disclosure may be applied to a piezoelectric generator having an oscillation circuit such as an integrated circuit (IC) for oscillating the piezoelectric vibrating piece.

What is claimed is:

1. A piezoelectric device, comprising:
a rectangular base plate, having a first face where a pair of mounting to terminals is formed, a second face opposite to the first face, where a bonding face is formed in a circumference, and a pair of connecting electrodes formed in the bonding face;
a rectangular piezoelectric vibrating piece, having a pair of excitation electrodes and lead electrodes extracted from the pair of the excitation electrodes, so that the lead electrode is fixed to the connecting electrode using a conductive adhesive;
a lid plate that covers the piezoelectric vibrating piece; and
a ring-shaped encapsulating material, arranged in a ring shape between the bonding face and the lid plate to encapsulate the base plate and the lid plate,
wherein, the connecting electrode is formed in a comb-tooth shape as seen from a normal direction of the second face to increase a lateral length of the connecting electrode in an area overlapped with the encapsulating material.

2. A piezoelectric device, comprising:
a rectangular base plate, having a first face where a pair of mounting terminals is formed, a second face opposite to the first face, and a pair of connecting electrodes formed in an edge portion of the second face;
a piezoelectric vibrating piece, having a vibrating portion where a pair of excitation electrodes is formed, a frame surrounding the vibrating portion, a connecting portion connecting the vibrating portion and the frame, and lead electrodes extracted from a pair of the excitation electrodes, the lead electrodes being connected to the connecting electrodes;
a lid plate, bonded to the frame; and
a ring-shaped encapsulating material, arranged in a ring shape between the bonding face and the frame to encapsulate the base plate and the piezoelectric vibrating piece,
wherein, the connecting electrode is formed in a comb-tooth shape as seen from a normal direction of the second face to increase a lateral length of the connecting electrode in an area overlapped with the encapsulating material.

3. The piezoelectric device according to claim 2, wherein the lead electrode is formed in a comb-tooth shape as seen from a normal direction of the second face to increase a lateral length of the lead electrode in an area overlapped with the encapsulating material.

4. The piezoelectric device according to claim 1, wherein the base plate includes a glass material or a piezoelectric material,
the connecting electrode includes a chrome layer directly formed on the glass material or the piezoelectric material and a surface layer formed on the chrome layer, and
a side face of the chrome layer is oxidized.

5. The piezoelectric device according to claim 4, wherein a nickel-tungsten alloy layer is included between the chrome layer and the surface layer.
